(19) United States
(12) Patent Application Publication
(10) Pub. No.: US 2006/0060977 A1
(43) Pub. Date: Mar. 23, 2006

(54) Semiconductor device

(75) Inventor: Takashi Kawanoue, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/231,749

(22) Filed: Sep. 22, 2005

(30) Foreign Application Priority Data
Sep. 22, 2004 (JP) P2004-274854

(51) Int. Cl. H01L 23/48

(52) U.S. Cl. 257/762

(57) ABSTRACT

A semiconductor device includes a low dielectric constant insulating layer formed above a semiconductor substrate having an element region, and a Cu wiring isolated by the low dielectric constant insulating layer. Between the low dielectric constant insulating layer and the Cu wiring, there is disposed an ionization suppressing layer containing an element with a work function of less than 3 eV as a simple substance, a Cu concentration of the ionization suppressing layer being less than 10 atomic percent.

### CROSS-REFERENCE TO THE INVENTION

This application is based upon and claims the benefit of priority from the prior Japanese Patent Application No. 2004-274854, filed on Sep. 22, 2004; the entire contents of which are incorporated herein by reference.

### BACKGROUND OF THE INVENTION

1. Field of the Invention

The present invention relates to a semiconductor device using a Cu wiring and a low dielectric constant insulating layer.

2. Description of the Related Art

In a semiconductor device, a Cu wiring to realize lower resistance of a wiring and an insulating layer with a low dielectric constant (low-k film) to reduce inter-wiring capacity are increasingly applied. In such a semiconductor device, since Cu is highly active and easy to diffuse into an insulating layer, a barrier layer for preventing diffusion of Cu is disposed between the Cu wiring and the insulating layer. Further, there are various suggestions about materials and structures of the barrier layer.

For example, in Japanese Patent Laid-open Application No. Hei 6-140400, there is described applying carbide such as Ti, Zr, and V to a barrier layer. In U.S. Pat. No. 6,518,648 B1, there is described using a high-temperature super conductive material layer as a barrier layer. Also in Japanese Patent Laid-open Application No. Hei 6-310509, there is described disposing a metal (Bi, Ga, Mg, Mn, or the like) which forms complete solid solution with Cu, around a barrier layer made of Ta, W, or a Ta-W alloy, as a trap layer.

On the other hand, as a semiconductor device becomes faster and more highly integrated recently, film thickness of a barrier layer gets gradually thinner. Therefore, it becomes increasingly difficult for a conventional barrier layer to prevent diffusion of Cu surely and sufficiently. Also, even in the structure described in the above patent document in which the trap layer is disposed, it becomes more difficult to prevent diffusion of Cu into an insulating layer perfectly, due to reduction of the total film thickness of the barrier layer and the trap layer.

When Cu in the Cu wiring diffuses into the insulating layer through the barrier layer, Cu ion drift occurs by an electric field at a time of device operation. In particular, when the low-k film is applied as the insulating layer, ionization of Cu by the electric field at the time of device operation and drift of Cu⁺ ions in the insulating layer are accelerated. When the drift of Cu⁺ ions occurs in the insulating layer, a short circuit or destruction of the Cu wiring may occur. Such a short circuit or destruction of the Cu wiring based on the drift of Cu⁺ ions becomes a lowering factor of a yield or reliability of the semiconductor device.

### SUMMARY OF THE INVENTION

A semiconductor device according to an embodiment of the present invention comprises a semiconductor substrate having an element region, a low dielectric constant insulating layer formed above the semiconductor substrate, a Cu wiring isolated by the low dielectric constant insulating layer, and an ionization suppressing layer disposed between the low dielectric constant insulating layer and the Cu wiring, the ionization suppressing layer containing an element with a work function of less than 3 eV as a simple substance, a Cu concentration thereof being less than 10 atomic percent.

A semiconductor device according to another embodiment of the present invention comprises a semiconductor substrate having an element region, a low dielectric constant insulating layer formed above the semiconductor substrate, a Cu wiring isolated by the low dielectric constant insulating layer, a barrier layer disposed between the low dielectric constant insulating layer and the Cu wiring, and an ionization suppressing layer disposed between the low dielectric constant insulating layer and the barrier layer, the ionization suppressing layer containing an element with a work function of less than 3 eV as a simple substance.

### BRIEF DESCRIPTION OF THE DRAWINGS

FIG. 1 is a cross-sectional view showing a structure of a semiconductor device according to an embodiment of the present invention.

FIG. 2 is a cross-sectional view showing a structure of a modification example of the semiconductor device shown in FIG. 1.

FIG. 3 is a cross-sectional view showing an element structure used for characteristics evaluation of the semiconductor device shown in FIG. 1.

### DESCRIPTION OF THE EMBODIMENTS

Hereinafter, embodiments for implementing the present invention will be described with reference to the drawings. The embodiments of the present invention will be hereinafter described based on the drawings, but it should be understood that the drawings are provided for the purpose of illustration only and are not intended to define the limits of the invention.

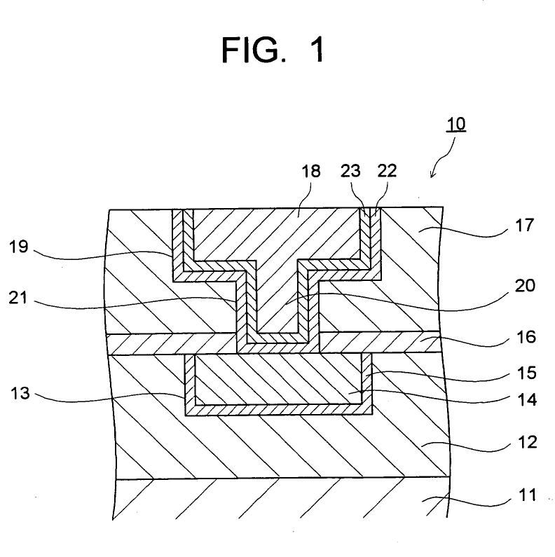

FIG. 1 is a cross-sectional view showing a structure of a semiconductor device according to an embodiment of the present invention. A semiconductor device 10 shown in FIG. 1 includes a first low dielectric constant insulating layer 12 formed above a semiconductor substrate 11 having an undepicted element region. For the low dielectric constant insulating layer 12, there is used a material whose relative dielectric constant (k-value) is 3.0 or below. As such a low dielectric constant insulating layer 12, there are exemplified a silicon oxide film (SiOC film) doped with carbon, an MSQ film (methyl silsesquioxane film), an HSQ (hydrogen silsesquioxane) film, a PAE (poly-arylene-ether) film and a porous film thereof, a porous silica film, and so on.

In the first low dielectric constant insulating layer 12, a wiring trench 13 is provided, and in this wiring trench 13 a first Cu wiring 14 is embedded and formed. A side surface and a bottom surface of the first Cu wiring 14 are surrounded by a first barrier layer 15. More specifically, in an interface between the first low dielectric constant insulating layer 12 and the first Cu wiring 14, there is disposed the first barrier layer 15 preventing diffusion of Cu. Further, a surface of the first Cu wiring 14 is covered by a SiCN film 16.

To the barrier layer 15, there can be applied various publicly known materials which have been conventionally used as barrier materials for Cu wirings. The barrier layer 15 is formed with an element having a barrier effect for Cu, or an alloy or a chemical compound including such an element. As such a barrier material for Cu, there can be cited a simple substance, an alloy, or a chemical compound (nitride, carbide, or the like) of at least one type of element selected from Ti, Zr, V, Nb, Ta and W, for example. However, the composing material of the barrier layer 15 is not limited to these.

Above the first low dielectric constant insulting layer 12 having the first Cu wiring 14, a second low dielectric constant insulating layer 17 is formed via the SiCN film 16. For the second low dielectric constant insulating layer 17, there is used a material whose relative dielectric constant (k-value) is 3.0 or below as in the first low dielectric constant insulating layer 12, and its specific composing material is the same as that of the first low dielectric constant insulating layer 12. In the second low dielectric constant insulating layer 17 there is formed a wiring trench 19 to be a forming portion of a second Cu wiring 18. Further, there is formed a via 20 for connecting the first Cu wiring 14 and the second Cu wiring 18. The via 20 is constructed by filling Cu in a via hole 21 formed in the second low dielectric constant insulating layer 17. The via 20 constitutes a part of the Cu wiring from the point of view of the semiconductor device 10.

In the above-described via hole 21 and the wiring trench 19, there are deposited an ionization suppressing layer 22 containing an element with a work function of less than 3eV as a simple substance, and a second barrier layer 23 in sequence. The ionization suppressing layer 22 and the second barrier layer 23 are deposited along inner wall surface of the via hole 21 and the wiring trench 19. In the via hole 21 and the wiring trench 19 on which the ionization suppressing layer 22 and the second barrier layer 23 are deposited in sequence, Cu is filled, and this Cu constitutes the via (connecting plug) 20 and the second Cu wiring 18. The ionization suppressing layer 22 is disposed on a side contacting the second low dielectric constant insulating layer 17, while the second barrier layer 23 is disposed on a side contacting the Cu wiring (via 20 and second Cu wiring 18).

The above-described damascene wiring is fabricated, for example, as follows. First, after a concave portion constructed with the via hole 21 and the wiring trench 19 is formed in the second low dielectric constant insulating layer 17 by dry etching or wet etching, the inside of the via hole 21 is cleaned. Next, along the entire inner wall surface of the via hole 21 and the wiring trench 19, the ionization suppressing layer (layer containing an element with a work function of less than 3 eV as a simple substance) 22 with a thickness of 1 nm, for example, is deposited. The ionization suppressing layer 22 is formed by a PVD method such as a sputtering method and a vapor deposition method, a CVD method, a plating method, or the like. Details of the ionization suppressing layer 22 will be described later.

Subsequently, on the ionization suppressing layer 22, there are deposited, for example, the barrier layer 23 made of a Ta film with a thickness of 1 nm and a seed Cu film with a thickness of 100 nm in sequence by the sputtering method or the like. Incidentally, to the barrier layer 23, there can be applied various publicly known materials which have been used as barrier materials for the Cu wiring, as in the case of the barrier layer 15, and a concrete composing material thereof is the same as that of the barrier layer 15. Subsequently, Cu is embedded in the via hole 21 and the wiring trench 19 by an electroplating method. Thereafter, the unnecessary Cu, barrier layer 23 and ionization suppressing layer 22 on the surface are removed by CMP. In this way, the via 20 connected to the first Cu wiring 14, and the second Cu wiring 18 are formed. A side surface and a bottom surface of the via 20 and the second Cu wiring 18 are surrounded by the barrier layer 23 and the ionization suppressing layer 22.

Here, when the thickness of the barrier layer 23 is made as thin as 1 nm, coverage of the via 20 and the second Cu wiring 18 by the barrier layer 23 may become incomplete. In particular, in the via 20 part where ratio of width w to depth d (d/w: aspect ratio) is large, it is highly possible that a formation state of the barrier layer 23 becomes discontinuous. As just described, if the coverage of the Cu wiring (via 20 and the second Cu wiring 18) by the barrier layer 23 is insufficient, due to thermal history and the like in a subsequent manufacturing process, Cu may leak to the second low dielectric constant insulating layer 17 from the side or bottom surface of the via 20 or the Cu wiring 18 through the barrier layer 23.

In a conventional semiconductor device, since Cu having leaked to a second low dielectric constant insulating layer 17 becomes Cu⁺ ions by an electric field at a time of device operation and then drifts, there is a possibility that it causes a short circuit or destruction of a second Cu wiring 18 or a first Cu wiring 14. In particular, in low dielectric constant insulating layers 12, 17, drift of the Cu⁺ ions tends to accelerate more easily than in a dense insulating film (SiO₂ film or the like), a short circuit or destruction of the Cu wiring occurs easily.

In the semiconductor device 10 of this embodiment, there is disposed the ionization suppressing layer 22 containing the element with the work function of less than 3 eV as the simple substance, between the via 20 and the second Cu wiring 18, and the second low dielectric constant insulating layer 17. To be precise, the ionization suppressing layer 22 is disposed between the second barrier layer 23 and the second low dielectric constant insulating layer 17 in order to suppress ionization of the Cu leaking through the second barrier layer 23.

The ionization suppressing layer 22 suppresses ionization of the Cu by thermionic emission from the element with the work function of less than 3 eV as the simple substance. More specifically, since the element with the work function of less than 3 eV as the simple substance which constitutes the ionization suppressing layer 22 emits thermal electrons, the ionization of the Cu leaking through the second barrier layer 23 is suppressed. If the work function of the element constituting the ionization suppressing layer 22 is 3 eV or over, it is not possible to emit the thermal electrons sufficiently. Therefore, an effect to suppress the ionization of the Cu cannot be sufficiently obtained.

As concrete examples of the elements with the work functions of less than 3 eV as the simple substances, there can be cited: Cs (2.1 eV), Rb (2.1 eV), Li (2.4 eV), Ba (2.5 eV), Sr (2.6 eV), Ca (2.9 eV), Eu (2.5 eV), Sm (2.7 eV), Ce (2.9 eV), and the like. Numerals in brackets depict the work functions of the respective elements as the simple substances. Among these, it is desirable to apply Cs or Rb in particular whose work function as the simple substance is small, in terms of enhancing a suppressing effect of the ionization of the Cu leaking through the barrier layer 23.

It is desirable to apply Li, Ba, Sr, Ca, Eu, Sm, or Ce whose melting point is high, in terms of enhancing a barrier property of the ionization suppressing layer 22. It is desirable to apply Li or Ca whose standard Gibbs free energy of formation of the oxide is smaller than that of Si, in terms of enhancing adhesiveness to the low dielectric constant insulating layer 17. It is desirable to apply Cs, Rb, Li, Ba, Sr, Ca, Eu, or Ce in which a natural isotope to become an emission source of alpha particles does not exist, in terms of preventing a soft error of the device. It is desirable to apply Ca which exists broadly and abundantly on the earth, in terms of manufacturing the device in large quantity and inexpensively.

The ionization suppressing layer 22 is formed of a simple substance, an alloy, a compound or the like of the element with the work function of less than 3 eV as the simple substance. As the compounds containing the element with the work function of less than 3 eV as the simple substance, there can be exemplified an intermetallic compound and chemical compounds such as an oxide, a sulfide, and a boride. As concrete examples of these compounds, there can be exemplified BaO, SrO, CaO, BaS and the like. Incidentally, if the ionization suppressing layer 22 is formed of an insulative compound, a part corresponding to a bottom surface of the via hole 21 of the ionization suppressing layer 22 should be removed by anisotropic reactive ion etching or the like as necessary.

As just described, to the composing material of the ionization suppressing layer 22, there can be applied not only the simple substance of the element with the work function of less than 3 eV as the simple substance but also the alloy, the compound and the like containing such an element. If the ionization suppressing layer 22 is formed of the alloy or the compound, it is preferable that 90 atomic percent or more of metal components in elements constituting the ionization suppressing layer 22 are the elements with work functions of less than 3 eV as the simple substances. If a concentration of the elements with the work functions of less than 3 eV as the simple substances among the metal element components is less than 90 atomic percent, it is possible that the effect of suppressing the ionization of the Cu is insufficient.

Further, a Cu concentration of the ionization suppressing layer 22 is set to be less than 10 atomic percent in order to obtain the ionization suppressing effect of the Cu. If the Cu concentration of the ionization suppressing layer 22 is 10 atomic percent or more, the thermal electrons emitted are consumed by the Cu in the ionization suppressing layer 22, so that the ionization of the Cu leaking from the Cu wiring through the second barrier layer 23 cannot be sufficiently suppressed. Also, the Cu contained in the ionization suppressing layer 22 may leak to the second low dielectric constant insulating layer 17. It is further preferable that the Cu concentration of the ionization suppressing layer 22 is less than 1 atomic percent. Also in view of the above, it is preferable that, among the metal element components constituting the ionization suppressing layer 22, a concentration of the elements with the work functions of less than 3 eV as the simple substances is 90 atomic percent or more.

The ionization suppressing layer 22 containing the element with the work function of less than 3 eV as the simple substance is only for suppressing the ionization of the Cu leaking through the second barrier layer 23 by thermionic emission, and the effect thereof can be achieved even if it does not have a uniform layer shape. Therefore, the ionization suppressing layer 22 can be a discontinuous film. As just described, the ionization suppressing layer 22 achieves the effect even if it is made partially exist between the via 20 and the second Cu wiring 18, and the second low dielectric constant insulating layer 17. Therefore, a film thickness of the ionization suppressing layer 22 is not specifically limited. However, when it is considered to obtain the ionization suppressing effect of the Cu with good repeatability, it is preferable that the film thickness of the ionization suppressing layer 22 is in a rage of 0.1 to 10 nm as an average film thickness.

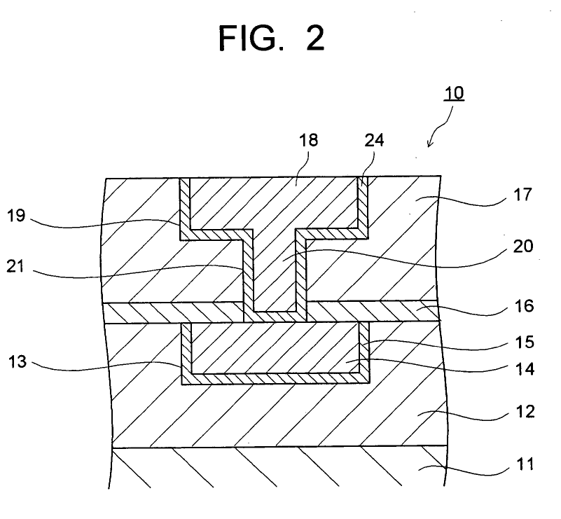

Types of usage of the ionization suppressing layer 22 are not limited to a stacked film with the barrier layer 23, but they can include making the element with the work function of less than 3 eV as the simple substance contained in the barrier layer 23, or making the barrier material for Cu stated above contained in the ionization suppressing layer 22. FIG. 2 shows a semiconductor device 10 in which an ionization suppressing layer 24 containing a barrier material for Cu is disposed between a Cu wiring (via 20 and second Cu wiring 18) and a second low dielectric constant insulating layer 17. As just described, also by the ionization suppressing layer 24 containing the barrier material for Cu, the effect of suppressing ionization of Cu can be obtained.

In the ionization suppressing layer 24 containing the barrier material for Cu, a concentration of the elements with the work functions of less than 3 eV as the simple substances is set accordingly in consideration of susceptibility that Cu may leak from the Cu wiring or that Cu drift may occur. When the ionization suppressing effect of the Cu is considered, among metal element components constituting the ionization suppressing layer 24 containing the barrier material for Cu, a concentration of the elements with the work functions of less than 3 eV as the simple substances is preferably 1 atomic percent or more, and further preferably 10 atomic percent or more. In the ionization suppressing layer 24 containing the barrier material for Cu, a Cu concentration is less than 10 atomic percent, and further preferably less than 1 atomic percent.

The ionization suppressing layer 22, as a substitute of the barrier layer 23 depending on the circumstances, can be disposed in an interface between the via 20 and the second Cu wiring 18, and the second low dielectric constant insulating layer 17. More specifically, a structure can be such that only the ionization suppressing layer 22 is disposed between the via 20 and the second Cu wiring 18, and the second low dielectric constant insulating layer 17, in the semiconductor device 10 shown in FIG. 1. As for a structure of the interface between the via 20 and the second Cu wiring 18, and the second low dielectric constant insulating layer 17, there can be cited a structure in which a stacked film of the barrier layer 23 and the ionization suppressing layer 22 is interposed, a structure in which the ionization suppressing layer 24 containing the barrier material for Cu is interposed, or a structure in which the ionization suppressing layer 22 is solely interposed.

Among the interface structures described above, the structure in which the stacked film of the barrier layer 23 and the ionization suppressing layer 22 is interposed suppresses diffusion of the Cu, and additionally prevents the ionization of the Cu leaking though the barrier layer 23. Therefore, it can be regarded as the most reliable structure. On the other hand, the ionization suppressing layer 24 containing the barrier material for Cu and the sole ionization suppressing layer 22 are able to further reduce thickness of a layer to be interposed in the interface between the Cu wiring (via 20 and second Cu wiring 18) and the second low dielectric constant insulating layer 17. Therefore, it is a structure effective for miniaturization of the Cu wiring. Incidentally, a structure other than these is applicable if an element with the work function of less than 3 eV as the simple substance exists in the interface.

Also, in the semiconductor device 10 of this embodiment, the stacked film of the barrier layer 23 and the ionization suppressing layer 22 or the ionization suppressing layer 24 containing the barrier material for Cu is disposed between the via 20 and the second Cu wiring 18, and the second low dielectric constant insulating layer 17. However, also in an interface between the first low dielectric constant insulating layer 12 and the first Cu wiring 14, the ionization suppressing layer 22 can be disposed in addition to the first barrier layer 15. Otherwise, the ionization suppressing layer 24 containing the barrier material for Cu can be disposed. The ionization suppressing layer is applicable to the whole Cu wirings.

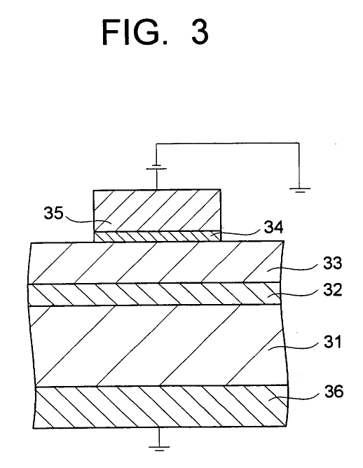

Next, evaluation results of characteristics of the above-described ionization suppressing layer 22 will be described. Here, a drift suppression effect of Cu⁺ ions by the ionization suppressing layer 22 is evaluated using a MIS (Metal Insulator Semiconductor) capacitor sample shown in FIG. 3 as a characteristics evaluation element. As the ionization suppressing layer 22 containing the element with the work function of less than 3 eV as the simple substance, each layer whose composing material is shown in Table 1 is applied. BTS (Bias Temperature Stress) tests of the respective MIS capacitors are performed and Cu drift amounts in the low dielectric constant insulating layers are evaluated from Vfb (Flatband Voltage) shifts at C-V measurement.

A concrete structure of the MIS capacitor (characteristics evaluation element) shown in FIG. 3 is as follows. On an n-Si substrate 31 there are formed a Si thermally oxidized film 32 with a film thickness of 40 nm and a low dielectric constant insulating layer 33 made of a SiOC film with a film thickness of 200 nm in sequence. On the low dielectric constant insulating film 33, the ionization suppressing layer 34 whose forming material is shown in Table 1 is formed to be 1 nm in thickness respectively. On the ionization suppressing film 34, there is formed a Cu electrode 35 with a diameter of 400 μm and a film thickness of 1 μm. As for a rear surface of the n-Si substrate 31, the Si thermally oxidized film is removed and an Al film 36 with a film thickness of 1 μm is formed.

The evaluation test is performed as follows. The MIS capacitor shown in FIG. 3 is heated to 100° C. and the Al film 36 of the rear surface of the n-Si substrate 31 is grounded, and then positive voltage is applied to the Cu electrode 35 such that an electric field in the low dielectric constant insulating layer 33 becomes +2 MV/cm, to perform the BTS test. After the BTS test is performed, the C-V measurement of the MIS capacitor is performed at a room temperature, to obtain Vfb from a C-V curve. When the Cu becomes Cu⁺ ions and drift into the low dielectric constant insulating layer 33 by a positive electric field at a time of the BTS test, Vfb shifts to a negative side. Then, the drift amount of the Cu in the low dielectric constant insulating layer 33 is evaluated from a difference in Vfb of an electrode to which the electric field is not applied. Measure results of the Vfb shift amount are shown in Table 1.

In Table 1, there are shown as comparative examples 1, measured results of Vfb amounts in cases that as substitutions of the ionization suppressing layers 34, layers are formed of the elements (Be, Mg, Sc, La, Lu and the like) with the work functions of 3 eV or over as the simple substances, and also a measured result of a Vfb Shift amount in a case that an intermediate layer is not formed between the low dielectric constant insulating layer 33 and the Cu electrode 35.

TABLE 1

| | | Ionization Suppressing Layer | | |
|---|---|---|---|---|
| | | | Work Function | |
| | Sample | Composing | as Simple | Vfb |
| | No. | Material | Substance (eV) | Shift (V) |
| Embodiment 1 | 1 | Cs | 2.1 | 0.1 |
| | 2 | Rb | 2.1 | 0.1 |
| | 3 | Li | 2.4 | 0.2 |
| | 4 | Ba | 2.5 | 0.2 |
| | 5 | Sr | 2.6 | 0.6 |
| | 6 | Ca | 2.9 | 0.8 |
| | 7 | Ce | 2.9 | 0.6 |
| | 8 | Sm | 2.7 | 0.9 |
| | 9 | Eu | 2.5 | 0.2 |
| | 10 | BaO | 2.5(Ba) | 0.2 |
| | 11 | SrO | 2.6(Sr) | 0.7 |
| | 12 | CaO | 2.9(Ca) | 0.8 |
| | 13 | BaS | 2.5(Ba) | 0.5 |
| Comparative | 14 | Be | 3.9 | 10.1 |
| Example 1 | 15 | Mg | 3.6 | 5.2 |
| | 16 | Sc | 3.5 | 4.8 |
| | 17 | La | 3.5 | 15.4 |
| | 18 | Lu | 3.3 | 9.7 |
| | 19 | (None) | — | 7.4 |

As is obvious from Table 1, in the elements (samples 14 to 18) having layers containing elements with the work functions of 3 eV or over as the simple substances as well as in the element having no intermediate layer (sample 19), large Vfb shifts occur. Therefore, it is known that the Cu drift occurs in the low dielectric constant insulating layers 33. On the other hand, in elements (samples 1 to 13) having the ionization suppressing layers 34 made of simple substances or compounds of elements with work functions of less than 3 eV as the simple substances, remarkable Vfb shifts are not noticed, and it is known that the Cu drift in the low dielectric constant insulating layers 33 is suppressed. It is inferred that it is because ionization of Cu in an interface between the ionization suppressing layer 34 and the low dielectric constant insulating layer 33 is suppressed by recombination with thermal electrons emitted from the element with a low work function, so that the Cu does not drift into the low dielectric constant insulating layer 33.

Next, there is evaluated an influence of the Cu concentration of the ionization suppressing layer on an effect of suppressing drift of Cu⁺ ions. To be more precise, in the MIS capacitor (characteristics evaluation element) shown in FIG. 3, Cu drift amounts in cases that the Cu concentrations of the ionization suppressing layers 34 made of Cs are varied, are evaluated based on Vfb shift amounts. The Vfb shift amounts are measured according to the method described above. Measured results of the Cu concentrations and the Vfb shift amounts in the ionization suppressing layers (Cs layers) 34 are shown in Table 2. Here, Cu is intentionally contained in the ionization suppressing layer 34 in order to examine the influence of the Cu concentration. Incidentally, in reference examples 1 in Table 2, the Cu concentrations of the ionization suppressing layers 34 are intentionally increased.

TABLE 2

| | | Ionization Suppressing Layer | | |
|---|---|---|---|---|
| | Sample | Composing | Cu Concentra- | Vfb |
| | No. | Material | tion (Atomic %) | Shift (V) |
| Embodiment 2 | 1 | Cs | 0 | 0.7 |
| | 2 | Cs—Cu | 0.01 | 0.4 |
| | 3 | Cs—Cu | 0.02 | 0.7 |
| | 4 | Cs—Cu | 0.04 | 0.3 |
| | 5 | Cs—Cu | 0.1 | 0.6 |
| | 6 | Cs—Cu | 0.2 | 0.3 |
| | 7 | Cs—Cu | 0.4 | 0.3 |
| | 8 | Cs—Cu | 1 | 1.1 |
| | 9 | Cs—Cu | 2 | 2.3 |
| | 10 | Cs—Cu | 4 | 3.7 |
| Reference | 11 | Cs—Cu | 10 | 8.2 |
| Example 1 | 12 | Cs—Cu | 20 | 8.3 |
| | 13 | Cs—Cu | 40 | 7.6 |
| | 14 | (None) | (100) | 7.9 |

As is obvious from Table 2, when the Cu concentration of the ionization suppressing layer 34 is 10 atomic percent and above, Vfb shift becomes prominent and it is known that the Cu drift occurs in the low dielectric constant insulating layers 33. On the other hand, in the elements (samples 1 to 10) having the ionization suppressing layers 34 with the Cu concentrations of less than 10 atomic percent, prominent Vfb shifts are not noticed, the Cu drift in the low dielectric constant insulating layers 33 being suppressed. It is known from these evaluation results that the Cu concentration of the ionization suppressing layer is preferable to be less than 10 atomic percent. Further, in order to increase the suppressing effect of the Cu drift and to enhance practicability, the Cu concentration of the ionization suppressing layer is desired to be less than 1 atomic percent.

As is known from the above-described evaluation results, by disposing an ionization suppressing layer containing an element with a work function of less than 3 eV as a simple substance between a Cu wiring and a low dielectric constant insulating layer, it becomes possible to suppress Cu drift in the low dielectric constant insulating layer. In suppressing the Cu drift with good repeatability, a Cu concentration of the ionization suppressing layer is set to be less than 10 atomic percent. Hereby, it is possible to effectively prevent a short circuit or destruction of the Cu wiring due to the Cu drift. This enhances a yield or reliability of a semiconductor device having a Cu wiring and a low dielectric constant insulating layer. Incidentally, it is obvious that, even in a structure in which a barrier material for Cu is contained in an ionization suppressing layer or a structure in which an ionization suppressing layer is solely disposed, the same effect can be obtained according to the above-described evaluation results.

It should be understood that the present invention is not limited to the above-described embodiments but can be modified in various ways without departing from the gist thereof in an execution phase. Also, the respective embodiments can be implemented combined appropriately as much as possible, and in that case a combined effect can be obtained. Further, inventions in various phases are included in the above-described embodiments, and various inventions may be extracted by an appropriate combination of a plurality of components disclosed.

What is claimed is:

1. A semiconductor device, comprising:
a semiconductor substrate having an element region;
a low dielectric constant insulating layer formed above the semiconductor substrate;
a Cu wiring isolated by the low dielectric constant insulating layer; and
an ionization suppressing layer disposed between the low dielectric constant insulating layer and the Cu wiring, the ionization suppressing layer containing an element with a work function of less than 3 eV as a simple substance, and a Cu concentration of the ionization suppressing layer being less than 10 atomic percent.

2. The semiconductor device as set forth in claim 1,
wherein the ionization suppressing layer is formed of at least one selected from a simple substance, an alloy and a compound of the element with the work function of less than 3 eV as the simple substance.

3. The semiconductor device as set forth in claim 1,
wherein the element with the work function of less than 3 eV as the simple substance is at least one selected from Cs, Rb, Li, Ba, Sr, Ca, Eu, Sm and Ce.

4. The semiconductor device as set forth in claim 1,
wherein the Cu concentration of the ionization suppressing layer is less than 1 atomic percent.

5. The semiconductor device as set forth in claim 1,
wherein the element with the work function of less than 3 eV as the simple substance accounts for 90 atomic percent or more of metal element components constituting the ionization suppressing layer.

6. The semiconductor device as set forth in claim 1,
wherein the ionization suppressing layer contains a barrier material for Cu.

7. The semiconductor device as set forth in claim 6,
wherein the ionization suppressing layer contains a simple substance, an alloy or a compound of at least one of element selected from Cs, Rb, Li, Ba, Sr, Ca, Eu, Sm and Ce, and a simple substance, an alloy or a compound of at least one of element selected from Ti, Zr, V, Nb, Ta and W.

8. The semiconductor device as set forth in claim 6,
wherein the element with the work function of less than 3 eV as the simple substance accounts for 1 atomic percent or more of metal element components constituting the ionization suppressing layer.

9. The semiconductor device as set forth in claim 6,
wherein the element with the work function of less than 3 eV as the simple substance accounts for 10 atomic percent or more of metal element components constituting the ionization suppressing layer.

10. The semiconductor device as set forth in claim 1,
wherein the low dielectric constant insulating layer has a relative dielectric constant of 3.0 or below.

11. The semiconductor device as set forth in claim 1,
wherein the ionization suppressing layer is formed along an inner wall surface of a concave portion constructed with at least one of a wiring trench and a via hole disposed in the low dielectric constant insulating layer, and the Cu wiring is filled in the concave portion having the ionization suppressing layer.

12. A semiconductor device, comprising:
a semiconductor substrate having an element region;
a low dielectric constant insulating layer formed above the semiconductor substrate;
a Cu wiring isolated by the low dielectric constant insulating layer;
a barrier layer disposed between the low dielectric constant insulating layer and the Cu wiring; and
an ionization suppressing layer disposed between the low dielectric constant insulating layer and the barrier layer, the ionization suppressing layer containing an element with a work function of less than 3 eV as a simple substance.

13. The semiconductor device as set forth in claim 12,
wherein the ionization suppressing layer is formed of at least one selected from a simple substance, an alloy and a compound of the element with the work function of less than 3 eV as the simple substance.

14. The semiconductor device as set forth in claim 12,
wherein the element with the work function of less than 3 eV as the simple substance is at least one selected from Cs, Rb, Li, Ba, Sr, Ca, Eu, Sm and Ce.

15. The semiconductor device as set forth in claim 12,
wherein the Cu concentration of the ionization suppressing layer is less than 10 atomic percent.

16. The semiconductor device as set forth in claim 12,
wherein the element with the work function of less than 3 eV as the simple substance accounts for 90 atomic percent or more of metal element components constituting the ionization suppressing layer.

17. The semiconductor device as set forth in claim 12,
wherein the barrier layer contains a simple substance, an alloy or a compound of at least one of element selected from Ti, Zr, V, Nb, Ta and W.

18. The semiconductor device as set forth in claim 12,
wherein the ionization suppressing layer has a film thickness of 0.1 to 10 nm.

19. The semiconductor device as set forth in claim 12,
wherein the low dielectric constant insulating layer has a relative dielectric constant of 3.0 or below.

20. The semiconductor device as set forth in claim 12,
wherein the ionization suppressing layer is formed along an inner wall surface of a concave portion constructed with at least one of a wiring trench and a via hole disposed in the low dielectric constant insulating layer, and the Cu wiring is filled in the concave portion having the ionization suppressing layer and the barrier layer.
